(19) United States
(12) Patent Application Publication
(10) Pub. No.: US 2025/0098300 A1
(43) Pub. Date: Mar. 20, 2025

(54) DISPLAY DEVICE AND MANUFACTURING METHOD THEREOF

(71) Applicant: AUO Corporation, Hsin-Chu (TW)

(72) Inventors: HSIN-HUA TSAI, Hsin-Chu (TW); Pei-Yun WANG, Hsin-Chu (TW)

(21) Appl. No.: 18/398,479

(22) Filed: Dec. 28, 2023

(30) Foreign Application Priority Data
Sep. 20, 2023 (TW) 112135916

(51) Int. Cl. H01L 27/12

(52) U.S. Cl. CPC H10D 86/60; H10D 86/0231; H10D 86/443

(57) ABSTRACT

A display device includes a substrate, an insulating layer and a metal layer. The substrate includes a light transmitting region. The insulating layer is disposed on the substrate and between the substrate and the metal layer. An edge of the insulating layer has a concave corner, and the concave corner is recessed toward the metal layer and located in the light transmitting region. A manufacturing method of the display device is also proposed.

### CROSS-REFERENCE TO RELATED PATENT APPLICATION

This non-provisional application claims priority to and the benefit of, pursuant to 35 U.S.C. § 119 (a), patent application Ser. No. 11/213,5916 filed in Taiwan on Sep. 20, 2023. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present disclosure relates to an electronic device, and particularly to a display device and a manufacturing method thereof.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In a manufacturing process of an electronic device, when manufacturing certain film layer patterns of each film layer (such as an insulating layer or a dielectric layer), the required etching depths thereof may be inconsistent, thus having the need for a longer etching time or the need for an etching method or an etchant with stronger physical or chemical properties. This results in unintended effects on other film layers (such as traces of a metal layer), which leads to a reduction in the critical dimension (CD) uniformity or even the possibility of line breakage.

FIG. 1 is a schematic view of a display device in the related art. For example, the display device 10 of FIG. 1 includes a substrate 100, an insulating layer 20, a metal layer 30, a conductive wire 31 formed by the metal layer 30, an active component region T and a light transmitting region TA in the substrate 100 region. In the process of manufacturing the light transmitting region TA, the insulating layer 20 needs to be etched to a greater depth, or in certain special requirements, the insulating layer 20 needs to be completely etched to expose the underlying substrate 100. This results in, when the conductive wire 31 is formed, a region of the metal layer 30 not easily covered by the photoresist solution being prone to be unintendedly etched, or exacerbation of the lateral etching effect. Thus, the conductive wire 31 has a large difference in the CD uniformity, or even has the breakage (such as the breakage DC in FIG. 1), such that the production yield of the display device is very low.

### SUMMARY

One aspect of the present disclosure provides a display device, in which the CD of the traces has good uniformity, with low possibility of breakage and high production yield.

The display device according to one embodiment of the present disclosure includes a substrate, an insulating layer and a metal layer. The substrate includes a light transmitting region. The insulating layer is disposed on the substrate and between the substrate and the metal layer. An edge of the insulating layer has a concave corner, and the concave corner is recessed toward the metal layer and located in the light transmitting region.

A manufacturing process of a display device according to one embodiment of the present disclosure includes: disposing a substrate, an insulating layer and a metal layer, wherein the insulating layer is between the substrate and the metal layer; disposing a first photoresist layer on the metal layer to perform a first photolithography process; performing a first etching process to the metal layer and the insulating layer to form a first patterned metal layer and a light transmitting region, and removing the first photoresist layer; disposing a second photoresist layer on the first patterned metal layer to perform a second photolithography process; and performing a second etching process to the first patterned metal layer and the insulating layer to form a second patterned metal layer and a concave corner located at an edge of the insulating layer, wherein the concave corner is recessed toward the second patterned metal layer and located in the light transmitting region.

Based on the foregoing, in the embodiments of the present disclosure, since the insulating layer of the display device is subjected to two etching processes, the edge of the insulating layer is repeatedly etched to form a concave corner facing toward the metal layer. The manufacturing process of the conductive wire includes performing two patterning processes to the metal layer, without the need to complete manufacturing of the conductive wire with a single patterning process, such that the conductive wire may have excellent CD uniformity, and the risk of breakage of the conductive wire is significantly reduced, thus effectively enhance the product yield of the display device.

The features and advantages of the present disclosure will become apparent and understandable from the embodiments taken in conjunction with the accompanying drawings in detail as follows.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a schematic view of a display device in the related art.

FIG. 2A is a top schematic view of a display device according to one embodiment of the present disclosure.

FIG. 2B is a sectional schematic view of FIG. 2A along the sectional line A-A′.

FIG. 3A to FIG. 3H are schematic views of a manufacturing process of a display device according to one embodiment of the present disclosure.

FIG. 3A to FIG. 3B and FIG. 3C′ to FIG. 3H′ are schematic views of a manufacturing process of a display device according to another embodiment of the present disclosure.

FIG. 4 is a sectional schematic view of a display device according to another embodiment of the present disclosure.

FIG. 5A and FIG. 5B are comparative schematic views of a critical dimension of the display device in the related art and the display device according to certain embodiments of the present disclosure.

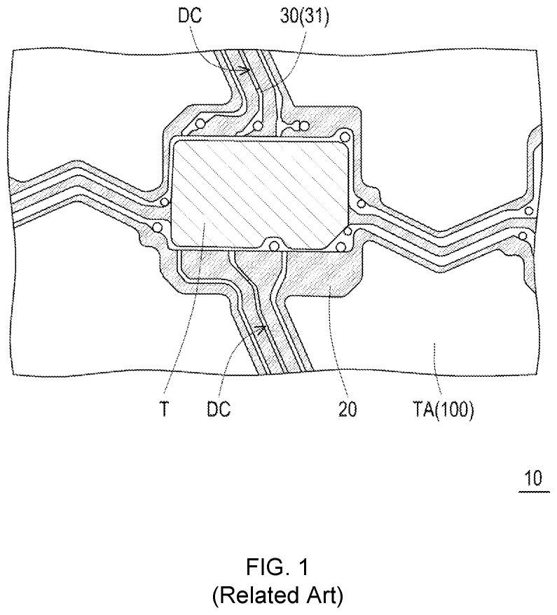

### DETAILED DESCRIPTION

The terms “about”, “approximately”, “essentially” or “substantially” as used herein shall cover the values described, and cover an average value of an acceptable deviation range of the specific values ascertained by one of ordinary skill in the art, where the deviation range may be determined by the measurement described and specific quantities of errors related to the measurement (that is, the limitations of the measuring system). For example, the term “about” represents within one or more standard deviations of a given value of range, such as within ±30 percent, within ±20 percent, within ±15 percent, within ±10 percent or within ±5 percent. Moreover, the terms “about”, “approximately”, “essentially” or “substantially” as used herein may selectively refer to a more acceptable deviation range or the standard deviation based on the measuring characteristics, the cutting characteristic or other characteristics, without applying one standard deviation to all characteristics.

In the accompanying drawings, for clarity purposes, the thickness of a layer, a film, a panel, a region, etc. may be enlarged. It should be understood that when one component such as a layer, a film, a region or a substrate is referred to as being disposed “on” the other component or “connected to” the other component, the component may be directly disposed on the other component or connected to the other component, or an intermediate component may also exist between the two components. In contrast, when one component is referred to as being “directly disposed on the other component” or “directly connected to” the other component, no intermediate component exists therebetween. As used herein, a “connection” may be a physical and/or electrical connection. In addition, when two components are “electrically connected”, other components may exist between the two components.

The present disclosure will now be described hereinafter in details with reference to the accompanying drawings, in which exemplary embodiments of the disclosure are shown. Whenever possible, identical reference numerals refer to identical or like elements in the drawings and descriptions.

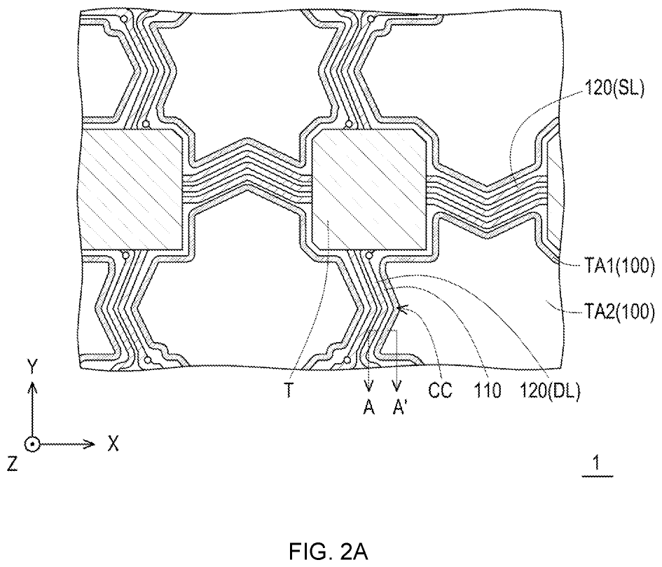

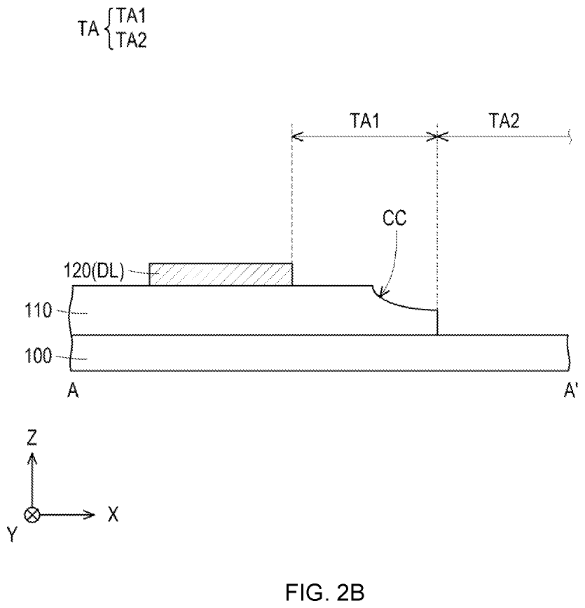

FIG. 2A is a top schematic view of a display device according to one embodiment of the present disclosure. FIG. 2B is a sectional schematic view of FIG. 2A along the sectional line A-A′. Referring simultaneously to FIG. 2A and FIG. 2B, the display device 1, in a thickness direction (such as the direction Z), includes a substrate 100, an insulating layer 110 and a metal layer 120 disposed sequentially. In other words, the insulating layer 110 is disposed on the substrate 100, and is disposed between the substrate 100 and the metal layer 120. In certain embodiments, the insulating layer 110 may directly contact the substrate 100, but the present disclosure is not limited thereto.

In other embodiments, other circuit layers, a dielectric layer, a buffer layer or an insulating layer assembled by multi-layered film layers may be provided between the insulating layer 110 and the substrate 100. The substrate 100 may be, for example, a transparent substrate. In one embodiment, the substrate 100 may be made of an inorganic transparent material (such as glass, quartz, other suitable materials or a combination thereof) or an organic transparent material (such as polyolefins, polyesters, polyalcohols, polyesters, thermoplastic polymers or thermosetting polymers, polycarbonates, other suitable materials or a combination thereof), without being limited thereto.

On the other hand, the substrate 100 may include a plurality of light transmitting regions TA in a plane direction (such as the direction X and the direction Y) thereof. When the display device 1 serves as a transparent display, each light transmitting region TA may further include a pixel electrode (not illustrated) made of a transparent conductive material to serve as the display pixel of the display device 1. The transparent conductive material is, for example, indium tin oxide, indium zinc oxide, indium oxide, tin oxide, other suitable materials or a combination thereof, without being limited thereto.

The material of the insulating layer 110 includes an inorganic insulating transparent material, such as silicon oxide, silicon nitride, silicon oxynitride, silicon carbide and other materials, or a combination thereof. In other embodiments, the insulating layer 100 may include, for example, a single-layered structure or a multi-layered structure, without being limited thereto.

The metal layer 120 may a film layer including a plurality of conductive wires of the display device 1, such as a plurality of data lines DL and a plurality of scan lines SL, to utilize the conductive wires to electrically connect the pixels of the display device 1. On the other hand, the display device 1 further include an active component region T and a plurality of active components (not illustrated) disposed in the active component region T to control the pixels. The active components may respectively include a source, a gate, a drain, a semiconductor channel layer, etc. However, the present disclosure is not limited thereto, and the active component region T may further include one or more storage capacitor structures. The data lines DL and the scan lines SL of the metal layer 120 may electrically connect the active components and other aforementioned components. In other embodiments, the metal layer 120 may be used to manufacture portions of the conductive structures (such as the source, the drain, the electrodes of the storage capacitor, etc.) of each component in the active component region T, and the present disclosure is not limited thereto. In other embodiments, a width of the conductive wires (such as the data lines DL and the scan lines SL) formed by the metal layer 120 may be approximately greater than or equal to 3 μm and less than or equal to 4 μm.

It should be noted that an edge of the insulating layer 110 facing toward the light transmitting region TA has a concave corner CC, and the concave corner CC is recessed toward the metal layer 120 and located in the light transmitting region TA. Specifically, in the direction X and the direction Y, the light transmitting region TA may include a first light transmitting region TA1 located at an edge of the light transmitting region TA, and a second light transmitting region TA2 located at a center of the light transmitting region TA. In other words, in the plane direction of the display device 1, the first light transmitting region TA1 is located between the metal layer 120 and the second light transmitting region TA2, and the second light transmitting region TA2 may be surrounded by the first light transmitting region TA1. Using FIG. 2B as an example, the first light transmitting region TA1 may be defined as a region from the boundary of the metal layer 120 to the boundary of the insulating layer 110, and the location of the concave corner CC may fall within the first light transmitting region TA1. However, the present disclosure is not limited thereto.

It should be noted that the second light transmitting region TA2 may expose the surface of the substrate 100. In other words, in a direction perpendicular to the surface of the display device 1, it is possible that the second light transmitting region TA2 does not include the insulating layer 110, such that when the display device 1 serves as a penetrating display device, the second light transmitting region TA2 having fewer film layers may reduce unexpected refraction and facilitate passing of the light beams, thus improving the light transmitting effect and the display quality. However, the present disclosure is not limited thereto. In other embodiments, the second light transmitting region TA2 may also include a portion of the insulating layer 110 without being completely removed.

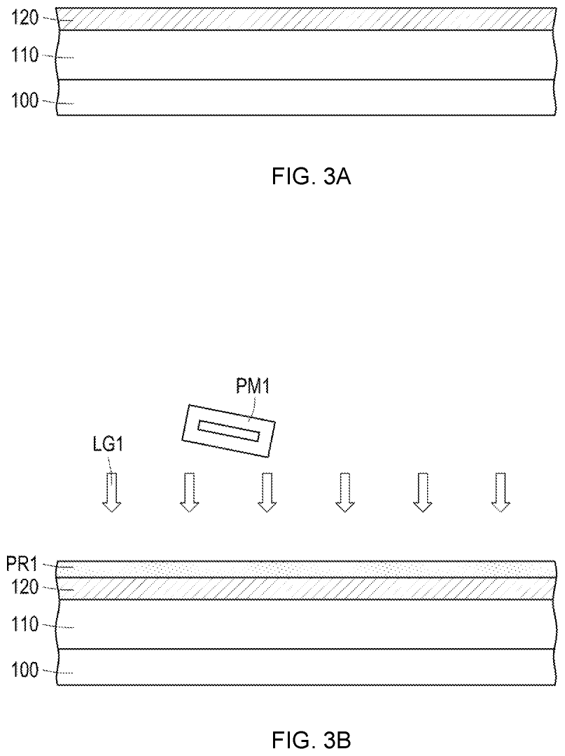

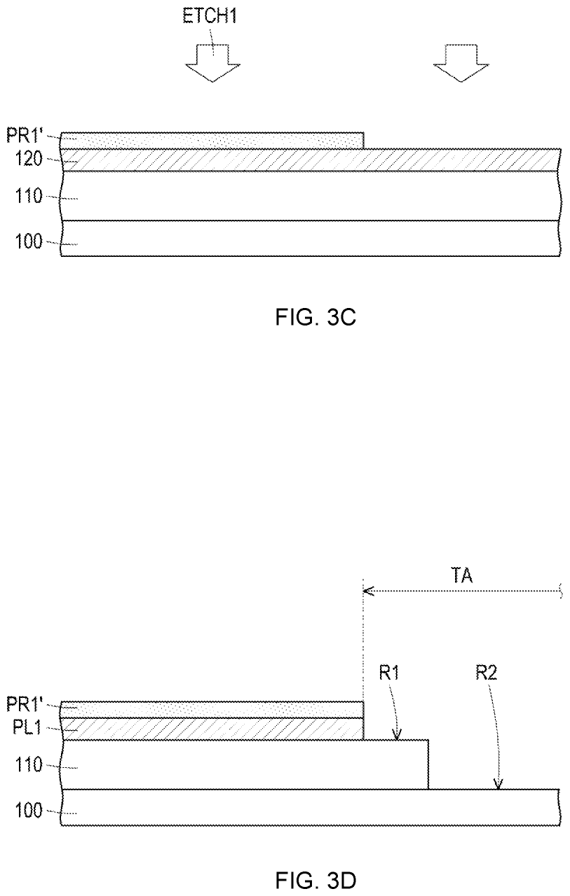

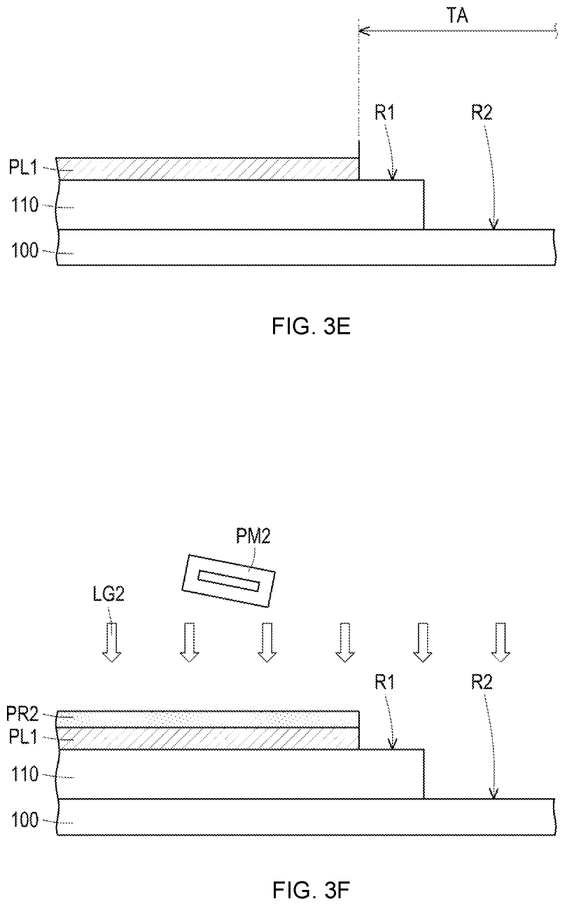

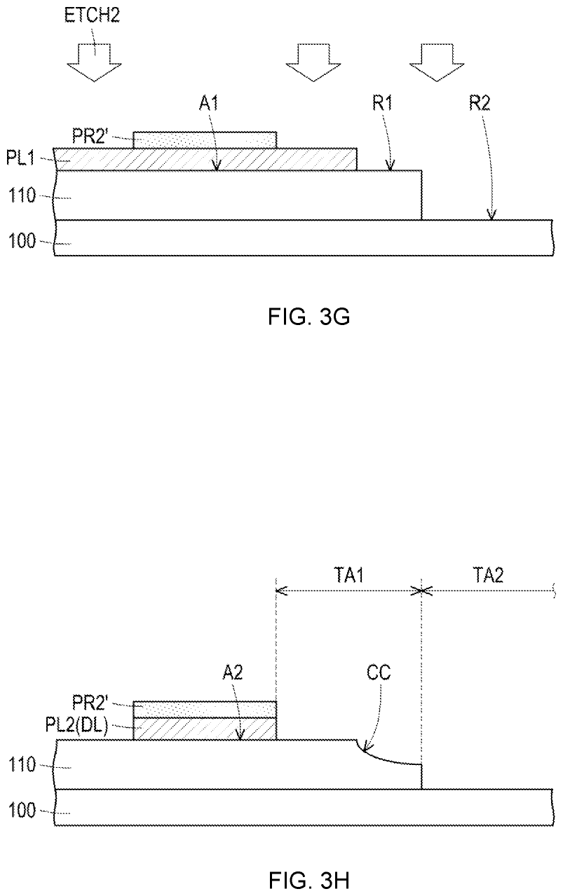

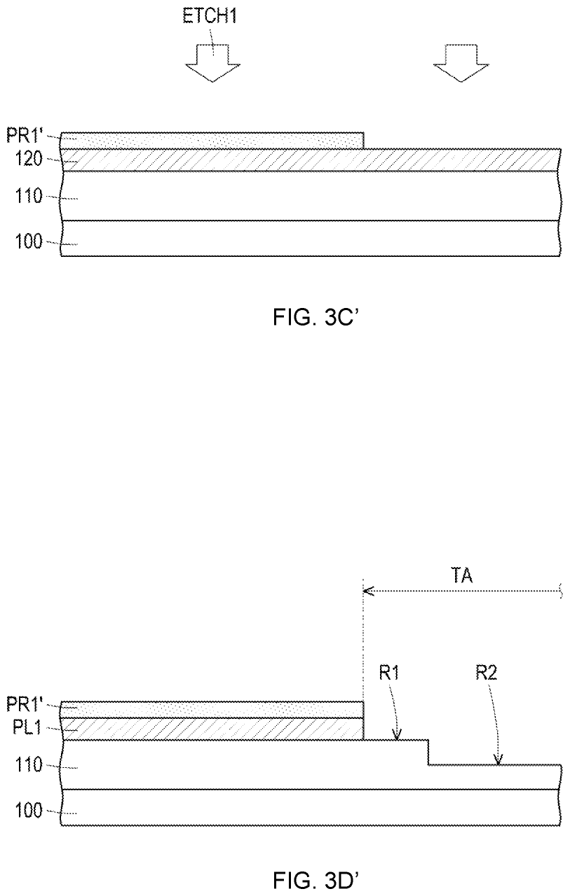

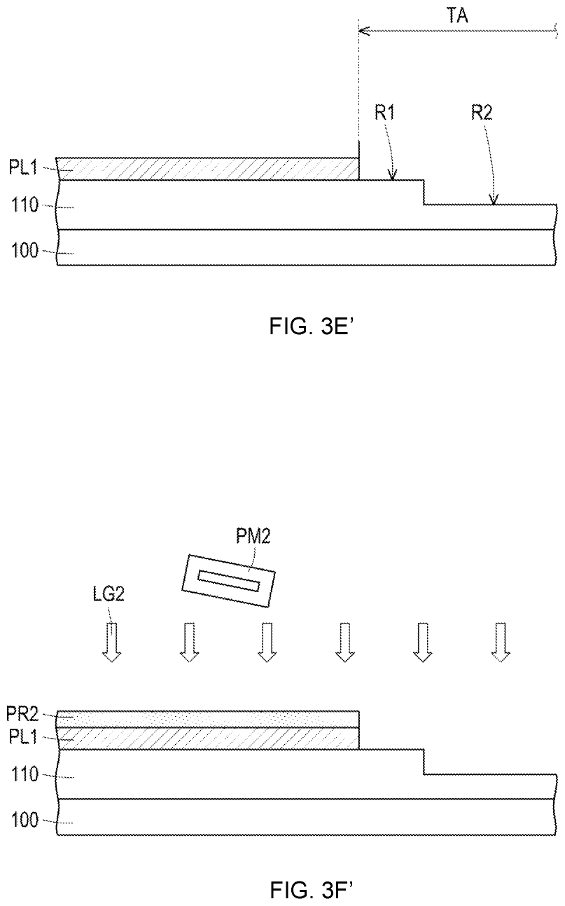

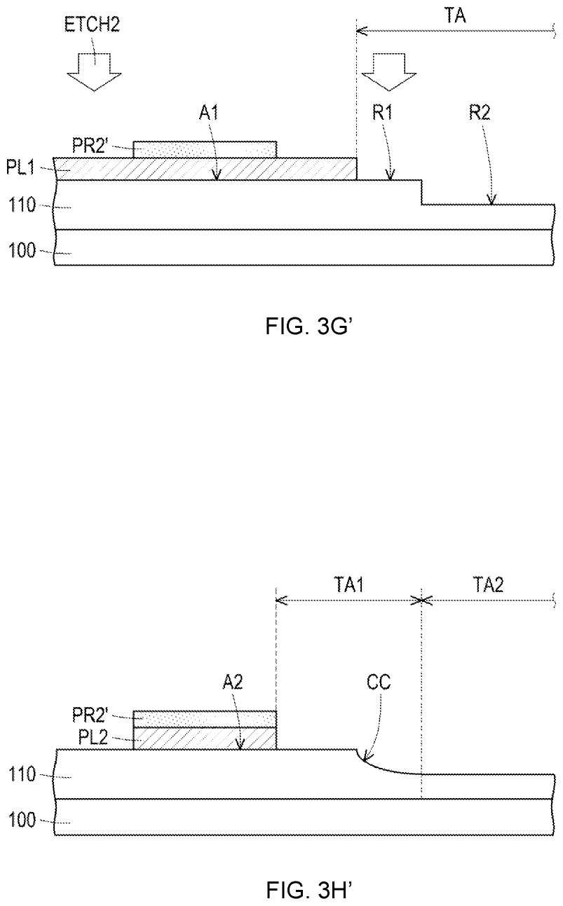

FIG. 3A to FIG. 3H are schematic views of a manufacturing process of a display device according to one embodiment of the present disclosure. The manufacturing process of the display device 1 is described in conjunction with the drawings as follows. Referring to FIG. 3A, firstly, a substrate 100 is provided, and an insulating layer 110 and a metal layer 120 are sequentially formed in a thickness direction of the substrate 100. In the present embodiments, the method of forming the insulating layer 110 and the metal layer 120, or the remaining film layers disposed therebetween and not illustrated, may be metal-organic chemical vapor deposition (MOCVD) or physical vapor deposition (PVD), without being limited thereto.

Referring to FIG. 3B and FIG. 3C, a first photoresist layer PR1 is disposed on the metal layer 110 to perform a first photolithography process LG1. The first photoresist layer PR1 may be, for example, a positive photoresist, but the present disclosure is not limited thereto. Prior to disposing the first photoresist layer PR1, steps of prebaking the insulating layer 110 and vapor coating a primer layer (such as hexamethyldisilazane, not illustrated) on the insulating layer 110 may be included to facilitate the coating and attaching of the first photoresist layer PR1. The method of disposing the first photoresist layer PR1 includes, for example, spin coating, but the present disclosure is not limited thereto. On the other hand, the first photolithography process LG1 includes: performing soft baking to a solution having the material of the first photoresist layer PR1 to remove a portion of the solvent in the first photoresist layer PR1; transferring an image on the first mask pattern PM1 to the first photoresist layer PR1 utilizing an exposure process; developing the image transferred from the first mask pattern PM1 utilizing a developing process to pattern the first photoresist layer PR1 to form a first pattern PR1′, where the region of the light shading pattern on the first mask pattern PM1 may substantially correspond to the region of the first pattern PR1′; and removing most of the solvent in the first pattern PR1′ by hard baking to increase the attachment and the anti-etching capability of the first pattern PR1′, but the present disclosure is not limited thereto. It should be noted that the pattern and the location of the light transmitting region TA may be preliminarily defined by the first mask pattern PM1 of the first photolithography process LG1.

Referring to FIG. 3C and FIG. 3D, subsequently, a first etching process ETCH1 is performed to the metal layer 120, the first pattern PR1′ and the insulating layer 110.

Through the mask formed by the first pattern PR1′, the regions of the first metal layer 120 and the insulating layer 110 not covered by the first pattern PR1′ are etched to further etch the first metal layer 120 to form a first patterned metal layer PL1. The first etching process ETCH1 may be wet etching or dry etching, and the present disclosure is not limited thereto. In addition, a first region R1 exposing the insulating layer 110 and a second region R2 exposing the substrate 100 may be further formed. In other words, in the second region R2, the insulating layer 110 may be completely removed. Thus, the first region R1 and the second region R2 may be defined as the light transmitting region TA of FIG. 2A and FIG. 2B, and the second region R2 exposing the substrate 100 may serve as the second light transmitting region TA2.

Referring to FIG. 3E and FIG. 3F, subsequently, the first pattern PR1′ formed by the first photoresist layer PR1 is removed to expose the first patterned metal layer PL1. The method of removing the first photoresist layer PR1 may be, for example, using a photoresist thinner to dissolve and remove the first pattern PR1′, but the present disclosure is not limited thereto. After removing the first photoresist layer PR1, the second photoresist layer PR2 is disposed on the first patterned metal layer PL1 to perform the second photolithography process LG2. For convenience of illustration, the drawings only illustrate the second photoresist layer PR2 disposed on the first patterned metal layer PL1, and the illustration of the second photoresist layer PR2 on the first region R1 and the second region R2 in the coating process is omitted. The method of disposing the second photoresist layer PR2 and the method of the second photolithography process LG2 are similar to the method of disposing the first photoresist layer PR1 and the method of the first photolithography process LG1, and are not herein further elaborated. By the second photolithography process LG2, the image of the second mask pattern PM2 may be transferred to the second photoresist layer PR2, and development is performed to form the second pattern PR2′ of FIG. 3G.

Continuing from above, the light shading region of the second mask pattern PM2 may substantially correspond to the region of the second pattern PR2′. It should be noted that the second mask pattern PM2 of the second photolithography process LG2 may be different from the first mask pattern PM1 of the first photolithography process LG1. In certain embodiments, the second mask pattern PM2 may correspond to the shapes and locations of the conductive wires (such as the data lines DL or scan lines SL) of the display device 1. From another perspective, the image and size of the second pattern PR2′ may be different from the image and size of the first pattern PR1′.

Referring to FIG. 3G and FIG. 3H, subsequently, a second etching process ETCH2 is performed to the first patterned metal layer PL1 and the insulating layer 110. In detail, a portion of the region of the first patterned metal layer PL1 not covered by the second pattern PR2′ and the first region R1 of the insulating layer 110 not covered by the first patterned metal layer PL1 are etched in the second etching process ETCH2. The method of the second etching process ETCH2 is similar to the method of the first etching process ETCH1, and is not herein elaborated.

Referring continuously to FIG. 3H, after the second etching process ETCH2 is completed, the first patterned metal layer PL1 is again patterned to form a second patterned metal layer PL2. The second patterned metal layer PL2 may be, for example, the data lines DL of the conductive wires, but the present disclosure is not limited thereto. The second patterned metal layer PL2 may also be the scan lines SL of the conductive wires. In certain embodiments, a projection area A1 of the first patterned metal layer PL1 of FIG. 3G onto the substrate 100 may be greater than a projection area A2 of the second patterned metal layer PL2 of FIG. 3H onto the substrate 100. It should be noted that, since the edge of the insulating layer 110, such as the first region R1, is repeatedly etched by the first etching process ETCH1 and the second etching process ETCH2, the concave corner CC is formed to be recessed toward the second patterned metal layer PL2, which is different from the general etching technology that an edge of the ladder structure forms a round corner protruding toward a direction away from the second patterned metal layer PL2 due to the processing precision. On the other hand, the concave corner CC is located in the light transmitting region TA, such as the first light transmitting region TA1. In other words, the location of the concave corner CC may overlap with the location of the first light transmitting region TA1.

Lastly, the second pattern PR2′ formed by the second photoresist layer PR2 may be dissolved and removed using a photoresist thinner, thus completing the architecture of the display device 1 of FIG. 2B. Compared to the case where the conductive wire structures and the light transmitting regions are formed in a single photolithography process, in the manufacturing process of the display device 1, the first photolithography process LG1 forming the light transmitting regions TA (including the first light transmitting region TA1 and the second light transmitting region TA2) is different from the second photolithography process LG2 forming the conductive wires. The metal layer 120 is subjected to two photolithography processes and two etching processes, thus ensuring the uniformity and completeness of the pattern formed by the metal layer 120, significantly reducing the possibility of breakage of the conductive wires, significantly enhancing the CD uniformity of the conductive wires and enhancing the product yield of the display device 1.

The present disclosure will be further described in details with some other embodiments, in which identical or similar components are identified by identical reference numerals, and descriptions of the identical technical contents will be omitted. The omitted descriptions may be referenced to in the aforementioned embodiment, and are not hereinafter reiterated.

FIG. 3A to FIG. 3B and FIG. 3C′ to FIG. 3H′ are schematic views of a manufacturing process of a display device according to another embodiment of the present disclosure. In other embodiments, the second light transmitting region TA2 may optionally keep a portion of the insulating layer 110. For example, referring to FIG. 3C′ and FIG. 3D′, when performing the first etching process ETCH1 to etch the insulating layer 110 and the metal layer 120 to form the light transmitting region TA and the first patterned metal layer PL1, it is possible not to completely remove the insulating layer 110 in the region not covered by the first pattern PR1′ of the first photoresist layer PR1. Thus, the light transmitting region TA may form the first region R1 having the insulating layer 110 that is thicker and a second region R2 having the insulating layer 110 with a thinner thickness.

Referring to FIG. 3E′ and FIG. 3F′, subsequently, the first pattern PR1′ is removed utilizing the photoresist thinner to expose the first patterned metal layer PL1, and the second photoresist layer PR2 is coated on the first patterned metal layer PL1 to subsequently perform the second photolithography process LG2. Similarly, the second photoresist layer PR2 coated on the first region R1 and the second region R2 is omitted herein in the illustration.

Referring to FIG. 3G′ and FIG. 3H′, by the second photolithography process LG2, the second photoresist layer PR2 is patterned to become the second pattern PR2′, and the second etching process ETCH2 is subsequently performed. The regions not covered by the second pattern PR2′ (such as the first region R1, the second region R2 and the first patterned metal layer PL1 not covered by the second pattern PR2′) may be further etched utilizing the second pattern PR2′ as the mask, thus forming the second patterned metal layer PL2 and forming the first light transmitting region TA1 repeatedly etched by the first etching process ETCH1 and the second etching process ETCH2 and the second light transmitting region TA2 with a portion of the insulating layer 110 not being etched. in the second etching process ETCH2. The second patterned metal layer PL2 may be, for example, data lines DL, but the present disclosure is not limited thereto. In other embodiments, the second patterned metal layer PL2 may be scan lines SL. It should be noted that, since the insulating layer 110 of the first light transmitting region TA1 is subjected to two etching processes, the concave corner CC may also be formed to be recessed toward the second patterned metal layer PL2.

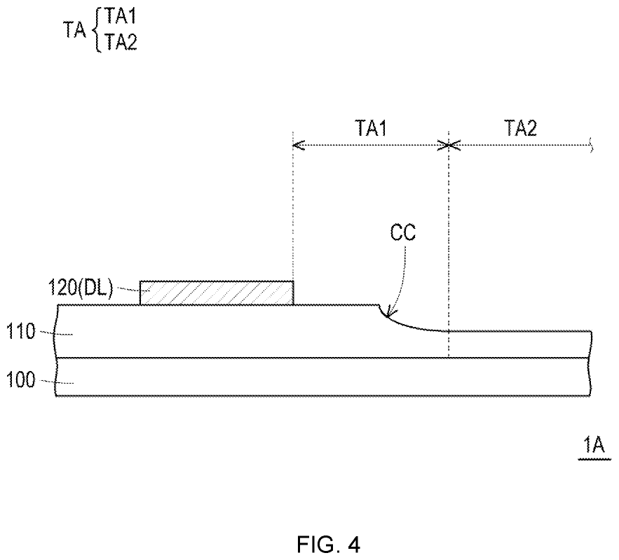

FIG. 4 is a sectional schematic view of a display device according to another embodiment of the present disclosure. Referring to FIG. 4, after the aforementioned steps are completed, the display device 1A of FIG. 4 may be formed by removing the second pattern PR2′, which is different from the display device 1 of FIG. 2B in that, in the display device 1A, the second light transmitting region TA2 has a portion of the first insulating layer 110 without being completely etched. With the aforementioned process, each conductive wire of the display device 1A may have uniform CD and higher yield, and the corresponding contents may be referenced to the aforementioned paragraphs without being herein elaborated.

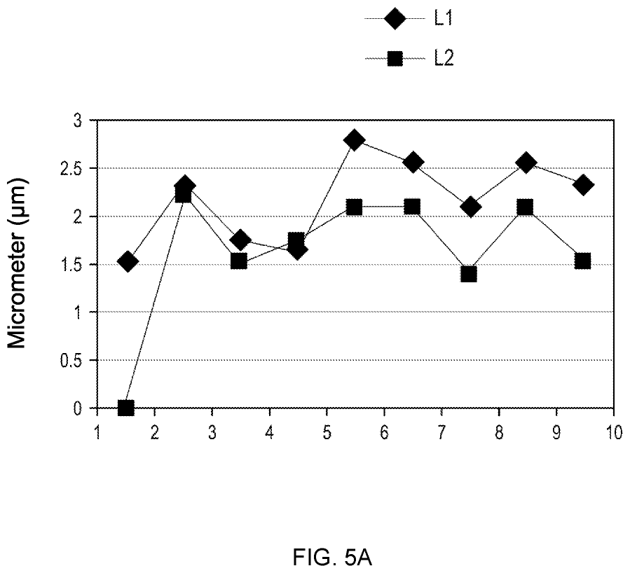

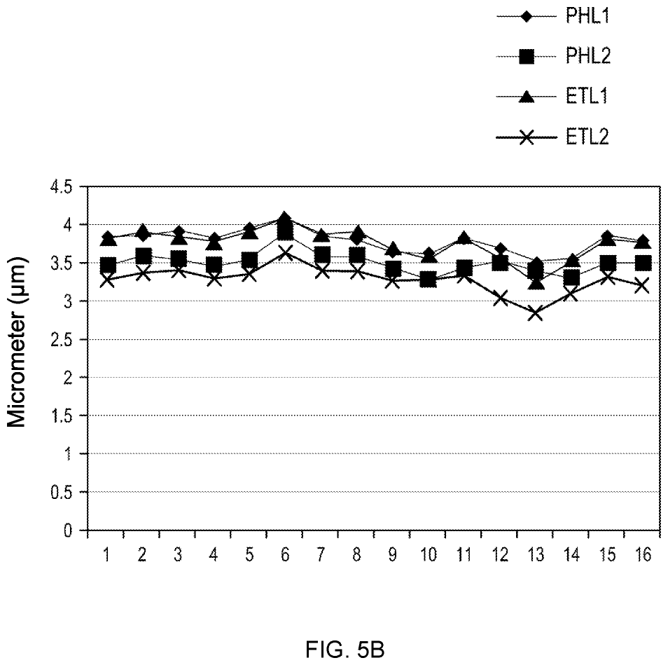

FIG. 5A and FIG. 5B are comparative schematic views of a critical dimension of the display device in the related art and the display device according to certain embodiments of the present disclosure. Referring firstly to FIG. 5A, the data L1 represents the corresponding CD (with the unit being μm) of 9 data points of a conductive wire 31 in a region of a typical display (such as the display device 10); and the data L2 represents the corresponding CD of 9 data points of another conductive wire 31 in another region of the typical display. It may be found that, whether it is the data L1 or the data L2, the conductive wire 31 has a large difference in the CD uniformity, and may be prone to breakage (such as the breakage DC), such as the data point of the data L1 where the CD is 0 μm. Thus, the display device 10 being produced has a low yield.

Referring to FIG. 5B, the data PHL1 represents the corresponding CD of the data points of a conductive wire formed after the second photolithography process LG2 in a region of the display device 1 (or the display device 1A) according to certain embodiments of the present disclosure; and the data ETL1 represents the corresponding CD of the data points of the conductive wire formed after the second etching process ETCH2 in a region of the display device 1 (or the display device 1A) according to certain embodiments of the present disclosure. Similarly, the data PHL2 represents the corresponding CD of the data points of a conductive wire formed after the second photolithography process LG2 in another region of the display device 1 (or the display device 1A) according to certain embodiments of the present disclosure; and the data ETL2 represents the corresponding CD of the data points of the conductive wire formed after the second etching process ETCH2 in another region of the display device 1 (or the display device 1A) according to certain embodiments of the present disclosure. It is understood from FIG. 5B that the conductive wires formed by the present embodiment may form the CD with high uniformity, and each conductive wire does not have breakage at the 16 data points, thus significantly enhancing the precision and yield of the pattern of each conductive wire, and effectively enhancing the product competitiveness of the display device 1 or the display device 1A.

In sum, in the embodiments of the present disclosure, since the insulating layer of the display device is subjected to two etching processes, the edge of the insulating layer is repeatedly etched to form a concave corner facing toward the metal layer. The manufacturing process of the conductive wire includes performing two patterning processes to the metal layer, without the need to complete manufacturing of the conductive wire with a single patterning process, such that the conductive wire may have excellent CD uniformity, and the risk of breakage of the conductive wire is significantly reduced, thus effectively enhance the product yield of the display device.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A display device, comprising:
a substrate, comprising a light transmitting region;
an insulating layer, disposed on the substrate; and
a metal layer, wherein the insulating layer is disposed between the substrate and the metal layer,
wherein an edge of the insulating layer has a concave corner, and the concave corner is recessed toward the metal layer and located in the light transmitting region.

2. The display device according to claim 1, wherein the light transmitting region comprises a first light transmitting region and a second light transmitting region, the first light transmitting region is located between the metal layer and the second light transmitting region in a plane direction of the display device, and the substrate is a glass substrate.

3. The display device according to claim 2, wherein a location of the concave corner overlaps with the first light transmitting region.

4. The display device according to claim 2, wherein the second light transmitting region does not include the insulating layer.

5. The display device according to claim 1, further comprising:
an active component; and
a conductive wire, electrically connected to the active component, wherein the metal layer comprises the conductive wire, and a width of the conductive wire is greater than 3 μm and less than or equal to 4 μm.

6. A manufacturing method of a display device, comprising:
disposing a substrate, an insulating layer and a metal layer, wherein the insulating layer is between the substrate and the metal layer;
disposing a first photoresist layer on the metal layer to perform a first photolithography process;
performing a first etching process to the metal layer and the insulating layer to form a first patterned metal layer and a light transmitting region, and removing the first photoresist layer;
disposing a second photoresist layer on the first patterned metal layer to perform a second photolithography process; and
performing a second etching process to the first patterned metal layer and the insulating layer to form a second patterned metal layer and a concave corner located at an edge of the insulating layer, wherein the concave corner is recessed toward the second patterned metal layer and located in the light transmitting region.

7. The manufacturing method of the display device according to claim 6, wherein materials of the first photoresist layer and the second photoresist layer are identical.

8. The manufacturing method of the display device according to claim 6, wherein the light transmitting region comprises a first light transmitting region and a second light transmitting region, the first light transmitting region is located between the metal layer and the second light transmitting region in a plane direction of the display device, and a location of the concave corner overlaps with the first light transmitting region.

9. The manufacturing method of the display device according to claim 8, wherein the second light transmitting region exposes the substrate.

10. The manufacturing method of the display device according to claim 8, wherein the second light transmitting region comprises a portion of the insulating layer.

11. The manufacturing method of the display device according to claim 6, wherein the second patterned metal layer comprises a conductive wire of the display device.

12. The manufacturing method of the display device according to claim 6, wherein a mask pattern of the first photolithography process is different from a mask pattern of the second photolithography process.

13. The manufacturing method of the display device according to claim 6, wherein a projection area of the first patterned metal layer onto the substrate is greater than a projection area of the second patterned metal layer onto the substrate.
